(19) United States
(12) Patent Application Publication
(10) Pub. No.: US 2013/0086441 A1
(43) Pub. Date: Apr. 4, 2013

(54) DYNAMICALLY SELF-RECONFIGURABLE DAISY-CHAIN OF TAP CONTROLLERS

(71) Applicants: Chang Yong Yang, Fayetteville, NC (US); Clint W. Mumford, Apex, NC (US); Yucong Tao, San Diego, CA (US); Craig E. Borden, Placenta, CA (US)

(72) Inventors: Chang Yong Yang, Fayetteville, NC (US); Clint W. Mumford, Apex, NC (US); Yucong Tao, San Diego, CA (US); Craig E. Borden, Placenta, CA (US)

(73) Assignee: QUALCOMM INCORPORATED, San Diego, CA (US)

(21) Appl. No.: 13/107,728

(22) Filed: Sep. 30, 2011

(51) Int. Cl. G01R 31/3177; G06F 11/25

(52) U.S. Cl. 714/727; 714/E11.155

(57) ABSTRACT

A self-reconfigurable daisy-chain of TAP controllers includes a main TAP controller and one or more auxiliary TAP controllers. The daisy-chain is dynamically self-reconfigurable in that the main TAP controller can configure and reconfigure the daisy-chain multiple times during the testing of a circuit. A data register within the main TAP controller is associated with a special JTAG instruction. This instruction is usable to enable and disable selected individual ones of the auxiliary TAP controllers. If an auxiliary controller is enabled, then it is made a part of the TDI-to-TDO daisy-chain scan path. If the auxiliary controller is disabled, then it is not a part of the daisy-chain scan path. A disabled controller and its registers are not, however, reset. A disabled controller can continue to supply test signals to the circuit under test. Using this mechanism, test time can be reduced by reducing the amount of shifting through slow controllers.

### BACKGROUND INFORMATION

1. Technical Field

The present disclosure relates to JTAG TAP controllers and to related circuitry and methods.

2. Background Information

FIG. 1 (Prior Art) is a diagram of a system to be tested. The system is a printed circuit board level system 1 involving multiple integrated circuits 2-5 that are interconnected by conductors of a printed circuit board 6. A test protocol and test mechanism commonly referred to as “JTAG” (Joint Test Action Group) is used. JTAG is standardized as IEEE standard 1149.1. Defects in the circuitry of the system of FIG. 1 can be present either in circuitry within the integrated circuits or in the conductors and circuitry of the printed circuit board that interconnect the integrated circuits. JTAG circuitry known as a boundary scan register is provided on each integrated circuit. This boundary scan register is usable to intercept signals passing between the core circuitry of the integrated circuit and the external terminals of the integrated circuit. In a test mode, such boundary scan circuitry can be made to disconnect the core circuitry from the integrated circuit terminals, to drive test signals into the core circuitry, and to read the test output signals generated by the core circuitry. In addition, the boundary scan circuitry is usable to test external connections on the printed circuit board extending between the boundary scan circuitry on one integrated circuit and the boundary scan circuitry on another integrated circuit.

The boundary scan circuitry of each integrated circuit is controlled by a Test Access Port controller (TAP controller). Each of the integrated circuits has its own TAP controller for controlling its own boundary scan circuitry. The TAP controller communicates with an outside JTAG test debugger functionality using standard JTAG signals TMS, TCK, TRST, TDI and TDO. The entire interface involving these signals by which the TAP controller communicates and is controlled is referred to as the Test Access Port (TAP). TDI stand for Test Data In. TDO stands for Test Data Out. TMS stands for Test Mode Select. TCK stands for Test Clock. TRST stands for Test Reset.

TAP controller 7 of integrated circuit 2 receives the TDI signal via terminal 8, receives the TMS signal via terminal 9, receives the TCK signal via terminal 10, receives the TRST signal via terminal 11, and outputs the TDO signal via terminal 12. By proper manipulation of the JTAG signals going into the TAP controller 2, the TAP controller 2 can be made to enter a test mode, to isolate internal core circuitry as described above, to use its boundary scan register to supply test signals to the core logic, to use its boundary scan register to capture test results back from the core logic, and to output the captured test results to the outside JTAG test debugger. In addition, the boundary scan circuitry of one integrated circuit may be made to drive a test signal out of one of its terminals and the boundary scan circuitry of another integrated circuit may be made to capture the signal as received on a terminal of the other integrated circuit so as to test an interconnecting conductor on the printed circuit board. Conductor 13 that extends from terminal 14 of integrated circuit 2 to terminal 15 of integrated circuit 3 is an example of such a conductor that can be tested. A JTAG connector 16 is typically provided on the printed circuit board 6 so that the outside JTAG test debugger can by physically connected to the printed circuit board so it can communicate with the TAP controllers.

As specified in JTAG standard IEEE-1149.1, TAP controllers can be interconnected together in a “Daisy-Chain” as illustrated in FIG. 1. The TDI port of the first TAP controller 7 is connected to the TDI terminal 18 of the JTAG connector 16. The TDO port 19 of the first TAP controller 7 is connected to the TDI port 20 of the second TAP controller 21. The TDO port 22 of the second TAP controller 21 is connected to the TDI port 23 of the third TAP controller 24. The TDO port 25 of the third TAP controller 24 is connected to the TDI port 26 of the fourth TAP controller 27, and the TDO port 28 of the fourth TAP controller 27 is connected to the TDO terminal 29 of the JTAG connector 16. By proper manipulation of the JTAG signals on terminals 18, 30, 31 and 32 of the JTAG connector 16, the outside JTAG test debugger can shift instructions and test data through the TDI-to-TDO daisy-chained TAP controllers. Similarly, test output data can be captured by JTAG circuitry in the various integrated circuits. The outside JTAG test debugger can then shift this test output data out of the various integrated circuits via the same TDI-to-TDO daisy-chain connection.

A JTAG daisy-chain is also usable to test blocks of logic within a single integrated circuit. Integrated circuits of today may be very large, and may involve multiple blocks of circuitry that are designed by different groups of people. A block may be designed by one company and the design may then be sold or licensed to another company that then incorporates the block into a larger integrated circuit along with other blocks designed by yet other companies. Due to the different circuitry in the various blocks, each block may have its own specialized test requirements. Accordingly, it is common for a block to be designed to have its own TAP controller and its own associated customized test circuitry. The entire block, including the TAP controller and the specialized test circuitry, is then provided as a single design for use by other companies and entities. When such a block is incorporated into a larger design and is fabricated as part of the larger integrated circuit, the circuitry of the block is to be tested. The TAP controller and the customized test circuitry of the block is used for this purpose. Such a block within a larger integrated circuit can therefore be conceptualized as the rough equivalent of an integrated circuit within a larger printed circuit board in the example of FIG. 1.

FIG. 2 (Prior Art) is a diagram of an integrated circuit 33 that includes four such blocks of circuitry 34-37. Each block has its own TAP controller and specialized test circuitry. The TAP controllers are interconnected in a daisy-chain fashion such that data and instructions and test output data can be shifted through one long scan path that extends from the TDI terminal 38, through the daisy-chain of TAP controllers 39-42, and out of the TDO terminal 43. Unfortunately, some of the blocks may be designed so that they can only shift such JTAG data and instructions at relatively slow rates. Other blocks may be able to shift such JTAG data and instructions at higher rates. If, for example, data is to be loaded into all the TAP controllers of the daisy-chain and if three of the TAP controllers are capable of shifting at 15 MHz but one TAP controller is only capable of shifting at 1 MHz, then the shift rate of the entire daisy-chain is limited to shifting at 1 MHz. Due to the slower than desired shift rate, the overall amount of time required to test the integrated circuit is undesirably large.

FIG. 3 (Prior Art) is a more detailed diagram of integrated circuit 33. Integrated circuit 33 has a configurable JTAG daisy-chain functionality. The configurable nature of the daisy-chain allows the daisy-chain of TAP controllers to be shifted at a higher clock rate in some situations. In addition to TAP controllers 39-42, integrated circuit 33 includes multiplexers 44-47, mode terminals 48 and 49, a decoder 50, and disable circuits 51-54. How the multiplexers and disable circuits are controlled is determined by the multi-bit digital value on the mode terminals 48 and 49.

FIG. 4 (Prior Art) is a diagram that illustrates a first configuration of the circuit of FIG. 3. The multiplexers 44-47 are controlled such that a serial scan path through the TAP controllers 39-42 extends from the TDI terminal 38, to the TDI input port of the TAP controller 39 of TAP controller 39, through the TAP controller 39 of Block A to the TDO output port of Block A, to the upper data input lead of multiplexer 44, through multiplexer 44 to the TDI input port of the TAP controller 40 of Block B, through the TAP controller of Block B to the TDO output port of TAP controller 40, to the upper data input lead of multiplexer 45, through multiplexer 45 to the TDI input port of the TAP controller 41 of Block C, and so forth to the TDO output terminal 43 as illustrated by the heavy lines in FIG. 4. The multi-bit digital value on mode terminals 48 and 49 is such that decoder 50 outputs the signals ENA, ENB, ENC, END, and MSEL to control the multiplexers 44-47 and the disable circuits 51-53 to set this configuration. In this configuration, none of the TAP controllers is disabled. The scan path extends in a daisy-chain fashion through all the TAP controllers.

FIG. 5 (Prior Art) is a diagram that illustrates a second configuration of the circuit of FIG. 3. In this example, two of the TAP controllers, TAP controller 39 and TAP controller 41, are disabled and the scan path does not extend through these TAP controllers. Control signals ENA and ENC are asserted to activate disable circuits 51 and 53. Disable circuits 51 and 53 block the TMS, TCK and TRST signals going into TAP controllers 39 and 41 so that these signals as received on the TAP controllers 39 and 41 are held at digital logic low values. These TAP controllers 39 and 41 are therefore held in the reset state in the sense that the individual bit locations of the data registers of the disabled TAP controllers 39 and 41 are either cleared or their output multiplexers are set such that the output signals of the bit locations are zeroed or are otherwise disturbed. Data retention in the data registers of the disabled TAP controllers 39 and 41 is not guaranteed. In the second configuration, multiplexers 44-47 are controlled such that the serial scan path through the TAP controllers extends from the TDI terminal 38, to the lower data input of multiplexer 44, through multiplexer 44 to the TDI input port of the TAP controller 40 of Block B, through the TAP controller of Block B to the TDO output port of TAP controller 40, to the upper data input lead of multiplexer 45, through multiplexer 45 to the lower input lead of multiplexer 46, through multiplexer 46 to the TDI input port of the TAP controller 42 of Block D, through the TAP controller of Block D to the lower input lead of multiplexer 47, through multiplexer 47, and to the TDO output terminal 43 of the integrated circuit. If, for example, TAP controllers 39 and 41 are only capable of shifting at a slower rate of 1 MHz as compared to TAP controllers 40 and 42 that can be shifted at a faster rate of 15 MHz, and if in this particular case a test to be performed does not require the use of TAP controllers 39 and 41, then the overall shift rate can be increased to 15 MHz by excluding TAP controllers 39 and 41 from the scan path as illustrated in FIG. 5.

### SUMMARY

A self-reconfigurable daisy-chain of TAP controllers includes a main TAP controller and one or more auxiliary TAP controllers. The daisy-chain is dynamically self-reconfigurable in that the main TAP controller can configure and reconfigure the daisy-chain multiple times during the testing of a circuit. In one example, a data register in the main TAP controller is associated with a special “JTAG Daisy-Chain Control Instruction” (JDCCI). The data register has a bit location for each of the auxiliary TAP controllers. If the bit location stores a first digital value, then the corresponding auxiliary TAP controller is enabled and is made a part of a TDI-to-TDO daisy-chain scan path extending from a TDI conductor (for example, TDI integrated circuit pad or package terminal) and a TDO conductor (for example, TDO integrated circuit pad or package terminal). If, on the other hand, the bit location stores a second digital value, then the corresponding auxiliary TAP controller is disabled and is not a part of the TDI-to-TDO daisy-chain scan path. The disabled auxiliary TAP controller and its data registers are not, however, reset. The contents and output signals of the data registers of the disabled auxiliary TAP controller are not shifted, cleared, reset or disturbed at all by the act of disabling the auxiliary TAP controller. The auxiliary TAP controller is said to be frozen. Such a disabled auxiliary TAP controller therefore can continue to supply test signals (in the form of data register output signals) to the circuit under test. Using this mechanism, the amount of test time required to rest an integrated circuit can be reduced by reducing the amount of shifting through slow TAP controllers.

The self-reconfigurable daisy-chain powers up such that all the auxiliary TAP controllers are initially disabled. After power up, the main TAP controller is usable to enable selected ones of the auxiliary TAP controllers and to reconfigure the daisy-chain such that enabled auxiliary TAP controllers are included in a TDI-to-TDO daisy-chain scan path.

In one operational example, a selected auxiliary TAP controller is made a part of the daisy-chain scan path and is set so that its data registers supply test signals to a circuit under test. The selected auxiliary TAP controller is then disabled by causing the main TAP controller to execute the special JDCCI instruction. To disable the selected auxiliary TAP controller, a digital low value is loaded into the bit location corresponding to the auxiliary TAP controller in the data register for the JDCCI instruction. The digital low value is loaded by shifting it into the bit location and then performing an update on the data register. The digital low value in this bit location causes the auxiliary TAP controller to be disabled. Because disabling the selected auxiliary TAP controller in this way does not reset the auxiliary TAP controller or its data registers, the contents and output signals of the data registers (of the selected auxiliary TAP controller) are not disturbed. The data registers continue to supply the test signals to the circuit under test even though the selected auxiliary TAP controller has been disabled and is no longer a part of a TDI-to-TDO daisy-chain scan path.

Next, the remaining TAP controllers that are part of the daisy-chain scan path as reconfigured are used to shift in and shift out instructions and test data so as to test the circuit under test. Where the disabled auxiliary TAP controller can only be clocked at a relatively slow clock rate as compared to the other TAP controllers, the disabling of the auxiliary TAP controller such that it is not a part of the daisy-chain scan path may allow the daisy-chain scan path to be clocked at a higher clock rate as compared to a conventional daisy-chain system where all TAP controllers that are used in a test are part of the TDI-to-TDO scan path. By increasing the rate at which the TAP controllers can be clocked using the self-reconfigurable daisy-chain architecture, the overall time required to test a circuit under test can be reduced. Selected ones of the auxiliary TAP controllers can be enabled and disabled dynamically as testing occurs by setting and clearing individual bit locations in the JDCCI data register of the main TAP controller via the JTAG test access port that is used to control the daisy-chain.

In one example, the dynamically self-reconfigurable daisy-chain architecture involves a main TAP controller, one or more auxiliary TAP controllers, and a block of logic referred to as the Top Level Multiplexing Module (TLMM). The TLMM includes a plurality of multiplexing circuits, an output multiplexing circuit, and an instance of TAP controller freeze logic for each auxiliary TAP controller. The TLMM may be provided as a predesigned block of circuitry that can be ported from one integrated circuit design to another.

In one advantageous aspect, the self-reconfigurable daisy-chain architecture is easily expandable at the time of integrated circuit design to accommodate adding more TAP controllers. To add another TAP controller, another multiplexing circuit is added to the TLMM, the output multiplexing circuit of the TLMM is made to have an additional data input lead, the data register for the JDCCI instruction in the main TAP controller is made to have another bit location to control the additional TAP controller, and another instance of the freeze logic is added to the TLMM. The additional TAP controller is then connected to the expanded TLMM circuit and the overall integrated circuit is fabricated. Which combinations of TAP controllers will be used together during which particular circuit test can be determined later after integrated circuit fabrication because the daisy-chain architecture is dynamically reconfigurable to include any combination of TAP controllers.

In another advantageous aspect, using the main TAP controller to reconfigure the daisy-chain of TAP controller eliminates the need for mode terminals. Eliminating mode terminals from the integrated circuit and its package reduces manufacturing cost and reduces the cost of the overall packaged integrated circuit.

The foregoing is a summary and thus contains, by necessity, simplifications, generalizations and omissions of detail; consequently, those skilled in the art will appreciate that the summary is illustrative only and does not purport to be limiting in any way. Other aspects, inventive features, and advantages of the devices and/or methods described herein, as defined solely by the claims, will become apparent in the non-limiting detailed description set forth herein.

### BRIEF DESCRIPTION OF THE DRAWINGS

FIG. 1 (Prior Art) is a diagram of a printed circuit board system that is tested using a daisy-chain of JTAG TAP controllers.

FIG. 2 (Prior Art) is a diagram of an integrated circuit that includes four blocks of circuitry where each block includes its own TAP controller and circuitry to be tested.

FIG. 3 (Prior Art) is a more detailed diagram of the JTAG daisy-chain circuitry of the integrated circuit of FIG. 2.

FIG. 4 (Prior Art) is a diagram that illustrates a first configuration of the circuit of FIG. 3.

FIG. 5 (Prior Art) is a diagram that illustrates a second configuration of the circuit of FIG. 3.

FIG. 6 is a diagram of an integrated circuit that includes a dynamically self-reconfigurable daisy-chain of TAP controllers in accordance with one novel aspect.

FIG. 7 is a more detailed diagram of the dynamically self-reconfigurable daisy-chain in the integrated circuit of FIG. 6.

FIG. 8 is a more detailed diagram of the main TAP controller of the dynamically self-reconfigurable daisy-chain of the integrated circuit of FIG. 6.

FIG. 9 is a more detailed diagram of the Top Level Multiplexing Module (TLMM) of FIG. 7.

FIG. 10 is a more detailed circuit diagram of one instance of the TAP controller freeze logic of FIG. 9.

FIG. 11A and FIG. 11B are a flowchart of a method 200 involving a self-reconfigurable daisy-chain of TAP controllers. In the method 200, one of the auxiliary TAP controllers (auxiliary TAP controller B) that was initially disabled after power up is then enabled and made a part of a TDI-to-TDO daisy-chain scan path, and then this auxiliary TAP controller B is disabled so that it is no longer a part of the TDI-to-TDO daisy-chain scan path.

FIG. 12 is a flowchart of a method 300 involving a dynamically self-reconfigurable daisy-chain of TAP controllers.

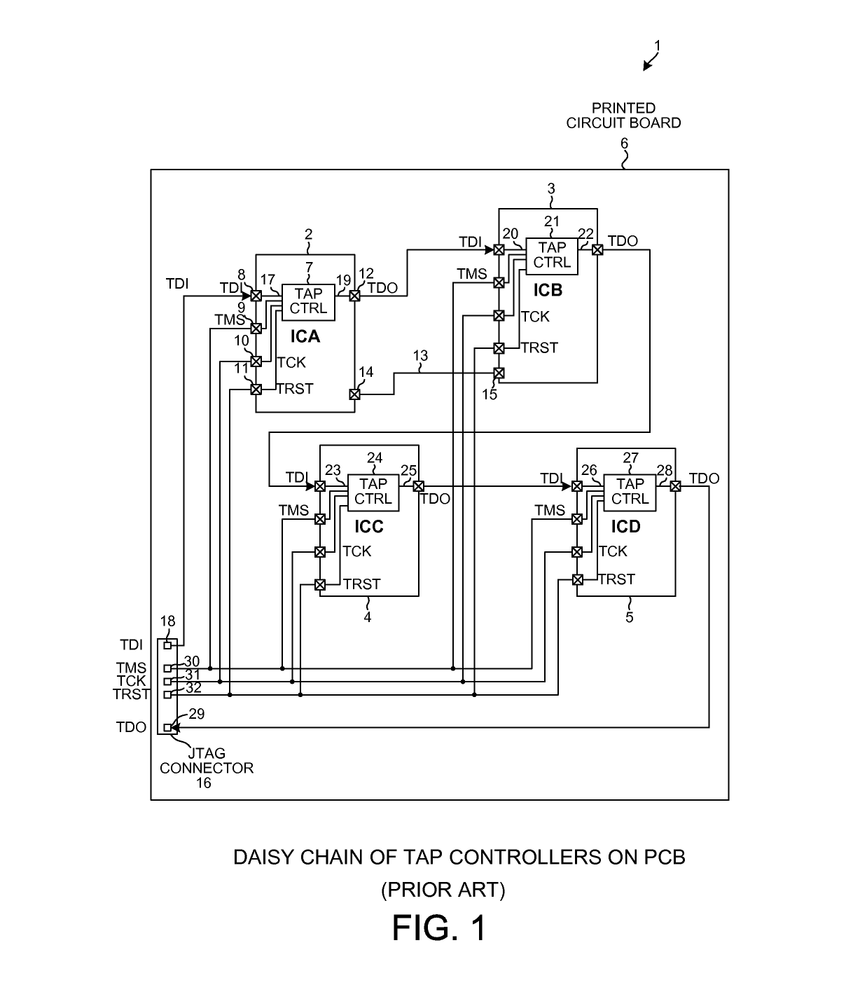

### DETAILED DESCRIPTION

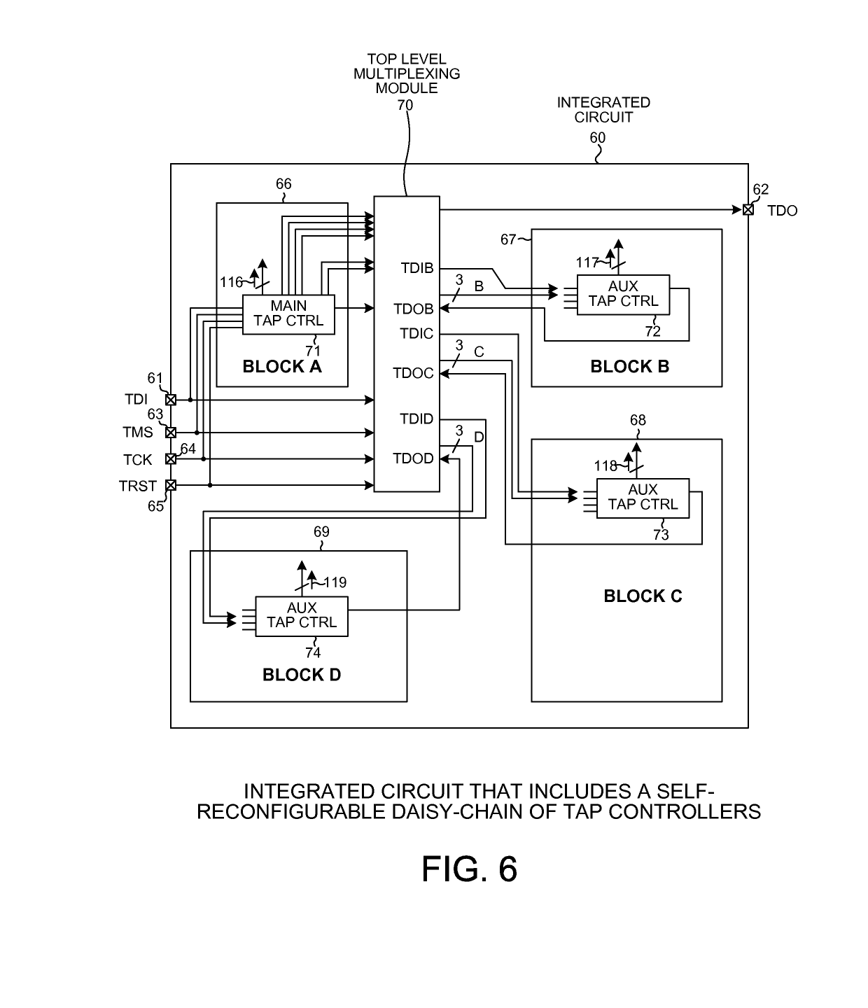

FIG. 6 is a diagram of an integrated circuit 60 in accordance with one novel aspect. Integrated circuit 60 includes a TDI terminal 61, a TDO terminal 62, a TMS terminal 63, and TCK terminal 64, a TRST terminal 65, four blocks of circuitry 66-69, and an another block of circuitry referred to here as the Top Level Multiplexing Module (TLMM) 70. Block A 66 includes a TAP controller 71. Block B 67 includes a TAP controller 72. Block C 68 includes a TAP controller 73. Block D 69 includes a TAP controller 74. TAP controller A 71 is referred to as the “main” TAP controller, whereas the other TAP controllers 72-74 are referred to as the “auxiliary” TAP controllers. Each of the blocks 66-69 includes, in addition to a TAP controller, other functional circuitry (not shown) that is to be tested by the TAP controller. Each TAP controller has data registers. Arrows 116-119 in FIG. 6 represent data register output signals as output from these data registers within TAP controllers 71-74, respectively. The different blocks 66-69 may be designed by different companies or different groups of people, and may then be included into an overall integrated circuit design that is designed by yet another company or group of people. An outside JTAG test debugger (not shown) can access and communicate with the TAP controllers by coupling to integrated circuit terminals 61-65.

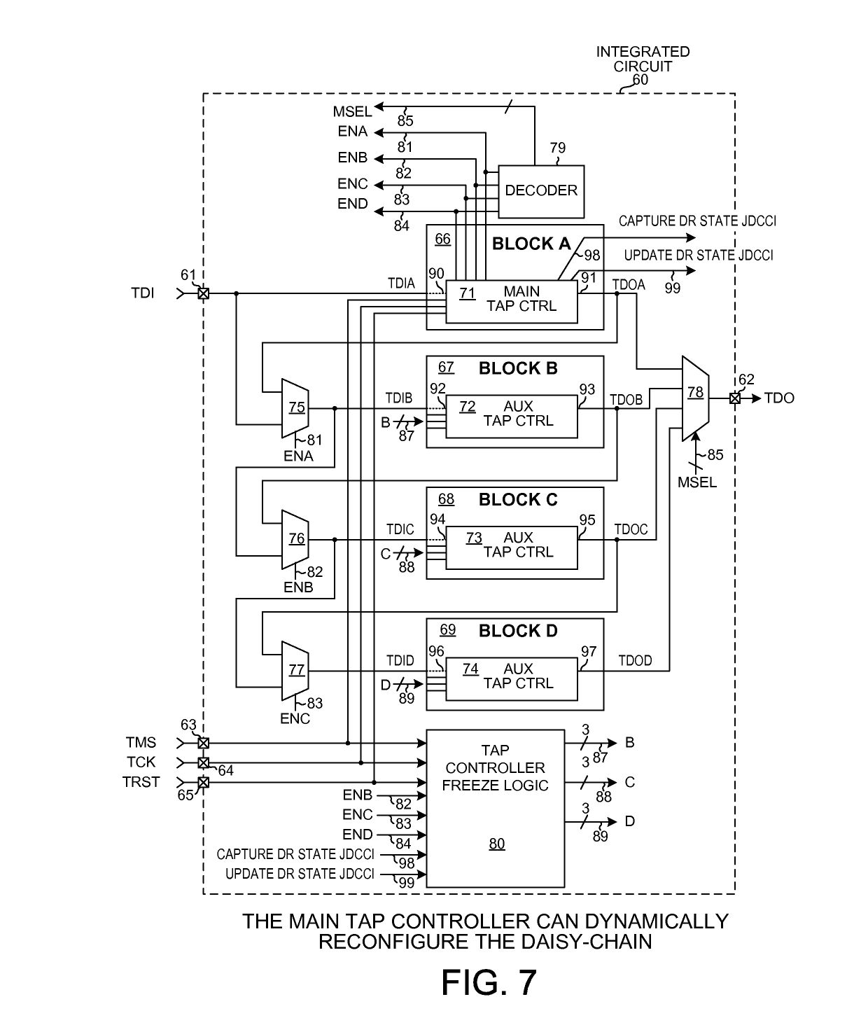

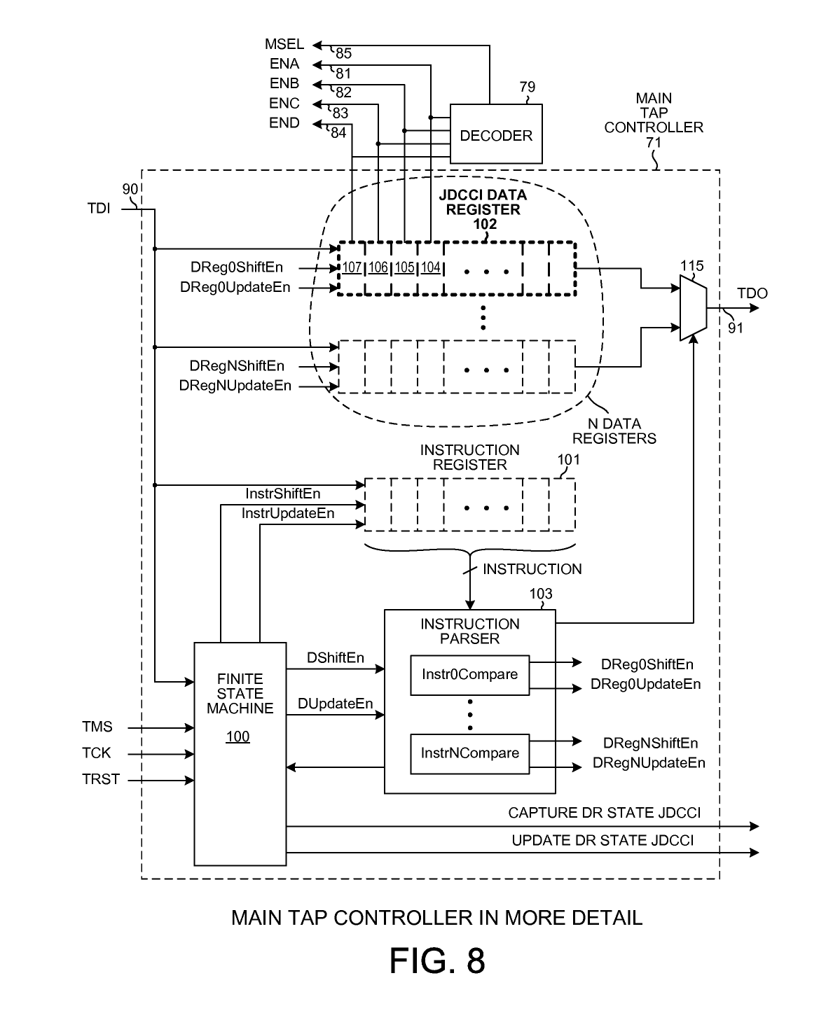

FIG. 7 is a more detailed diagram of the integrated circuit 60 of FIG. 6. The multiplexing circuits 75-78, the decoder 79, and the TAP controller freeze logic 80 of FIG. 7 are parts of the TLMM block 70 of FIG. 6. TAP controller 71 includes a data register. This data register includes many bit locations. When the data register is made part of the TDI-to-TDO scan path, digital values are shifted through these bit locations so that one digital value is present in each bit location. As is understood in the JTAG arts, after an update is executed on the data register, the digital value in a bit location is made to appear on a corresponding data output of the bit location. In FIG. 7, conductor 81 extends from the data output of a first bit location 104 (see FIG. 8) of the data register. This conductor 81 supplies a digital value ENA stored in the first bit location 104 to multiplexing circuit 75 and to decoder 79. Similarly, conductor 82 is coupled to a data output of a second bit location 105 of the data register and supplies a digital value ENB stored in the second bit location 105 to multiplexing circuit 76, to decoder 79 and to TAP controller freeze logic 80. Similarly, conductor 83 is coupled to a data output of a third bit location 106 of the data register and supplies a digital value ENC stored in the third bit location 106 to multiplexing circuit 77, to decoder 79 and to TAP controller freeze logic 80. Similarly, conductor 84 is coupled to a data output of a fourth bit location 107 of the data register and supplies a digital value END stored in the fourth bit location 107 to decoder 79 and to TAP controller freeze logic 80.

Multiplexing circuits 75-77 in this example are two-to-one digital multiplexers where the digital values ENA, ENB and ENC are supplied onto the select input leads of multiplexers 75-77, respectively. Decoder 79 decodes the ENA, ENB, ENC and END values and generates therefrom the multi-bit digital control value MSEL. MSEL is supplied via conductors 85 onto the select input leads of output multiplexing circuit 78. Accordingly, the digital values ENA, ENB, ENC and END stored in the data register in TAP controller 71 determine how the multiplexing circuits 75-78 configure the daisy-chain of TAP controllers.

In addition to a data register, main TAP controller 71 includes an instruction register and a finite state machine (FSM) as specified by IEEE-1149.1. If the finite state machine is in the Capture-DR state when executing a special “JTAG Daisy-Chain Control Instruction” (JDCCI), then TAP controller 71 asserts the signal digital CAPTURE DR STATE JDCCI onto conductor 98 and this signal is communicated to TAP controller freeze logic 80. Similarly, if the finite state machine is in the Update-DR state when executing the special JDCCI instruction, then TAP controller 71 asserts the signal UPDATE DR STATE JDCCI onto conductor 99 and this signal is communicated to TAP controller freeze logic 80. The three conductors 87 labeled with reference numeral B carry TMS, TCK and TRST signals on three separate conductors to TAP controller 72. These signals, as they enter TAP controller B 72, are designated TMSB, TCKB and TRSTB, respectively. Similarly, the three conductors 88 labeled with reference numeral C carry TMS, TCK and TRST signals on three separate conductors to TAP controller 73. These signals, as they enter TAP controller C 73, are designated TMSC, TCKC and TRSTC, respectively. The three conductors 89 labeled with reference numeral D carry TMS, TCK and TRST signals on three separate conductors to TAP controller 74. These signals, as they enter TAP controller D 74, are designated TMSD, TCKD and TRSTD, respectively.

The TDI port and the TDO port of TAP controller 71 are identified with reference numerals 90 and 91, respectively. The TDI port and the TDO port of TAP controller 72 are identified with reference numerals 92 and 93, respectively. The TDI port and the TDO port of TAP controller 73 are identified with reference numerals 94 and 95, respectively. The TDI port and the TDO port of TAP controller 74 are identified with reference numerals 96 and 97, respectively.

FIG. 8 is a more detailed diagram of main TAP controller A 71. Main TAP controller 71 includes the FSM 100, the instruction register 101, the data register 102 for the JDCCI instruction, other data registers associated with other instructions, an instruction parser 103, and an output multiplexing circuit 115. There are multiple different instructions that can be loaded into instruction register 101. There is one data register associated with each instruction. In one typical operation, an instruction is loaded into instruction register 101 under the control of the FSM 100 by serially shifting bits of the instruction in through the TDI port 90 and into the instruction register 101. Once the instruction is in the instruction register, and the instruction register has been updated, the instruction parser 103 identifies what kind of instruction has been loaded. If, for example, the instruction is the special JDCCI instruction, then the corresponding “Instr0Compare” circuit detects the JDCCI instruction and asserts the DReg0ShfitEn signal. This enables shifting of the Reg0. Reg0 in this case is data register 102 that is associated with the JDCCI instruction. The data bits are then serially loaded via the TDI port 90 into the enabled data register Reg0. Once all the data bits have been shifted into corresponding bit locations in data register 102, the parser asserts the DReg0UpdateEn signal such that the data register is updated with the new digital data values shifted in. At the time of the update, the newly shifted in data values also appear on conductors 81-84. Bit location 104 is the bit location in data register 102 that stores the ENA value. Bit location 105 is the bit location in data register 102 that stores the ENB value. Bit location 106 is the bit location in data register 102 that stores the ENC value. Bit location 107 is the bit location in data register 102 that stores the END value.

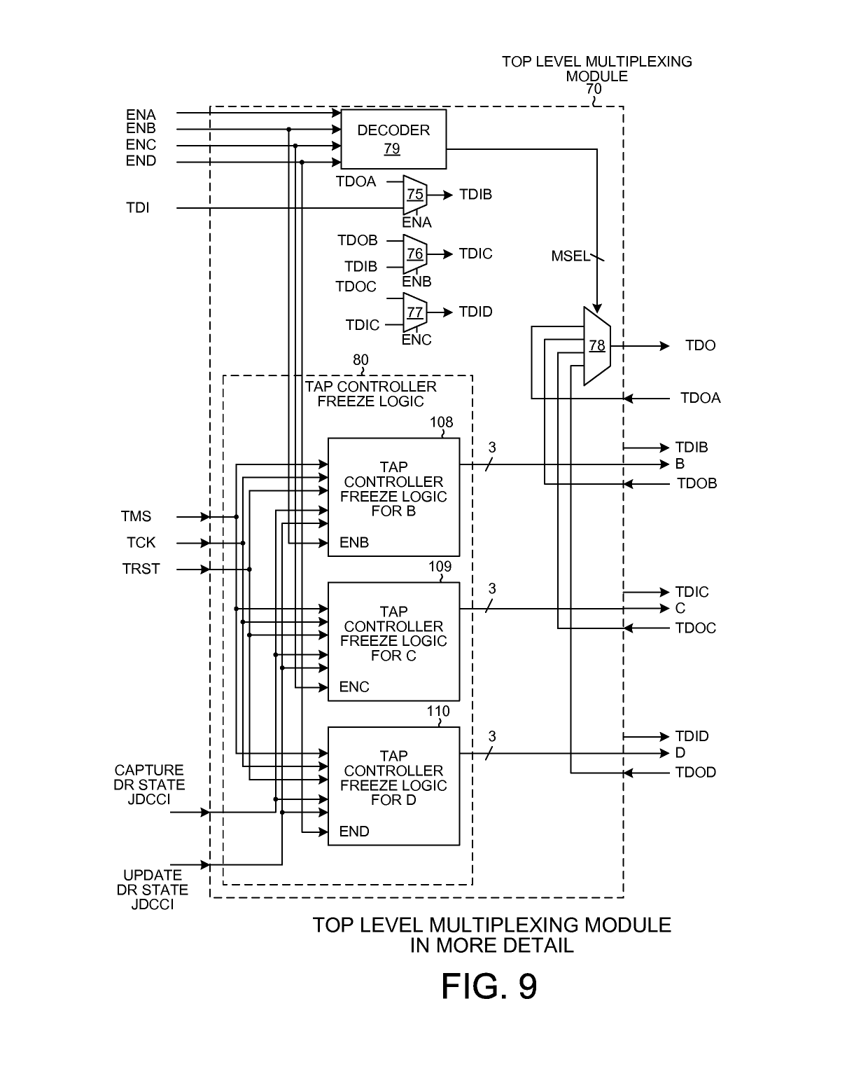

FIG. 9 is a more detailed diagram of the Top Level Multiplexing Module (TLMM) 70 of FIG. 6. TAP controller freeze logic 80 actually includes three TAP control freeze logic circuits 108-110, one for each of the auxiliary TAP controllers 72-74, respectively. The circuitry of TLMM 70 is in this example designed as a separate block of logic that is to be instantiated as a unit separately from the other blocks 66-69. In this way, the logic of TLMM 70 is localized into one area of the fabricated integrated circuit 60 as its own block of logic.

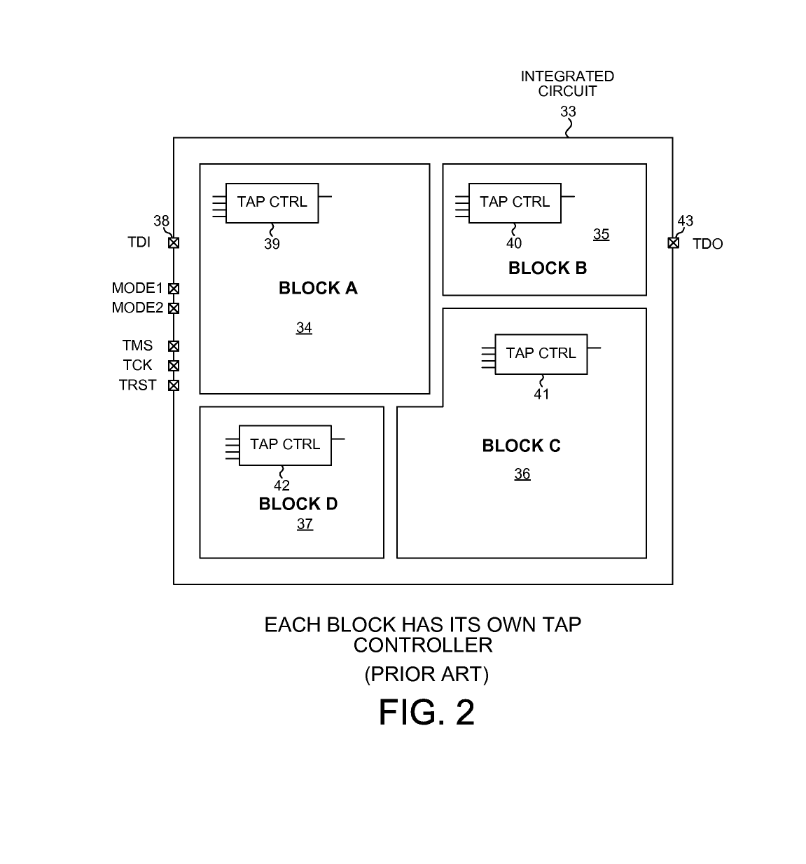

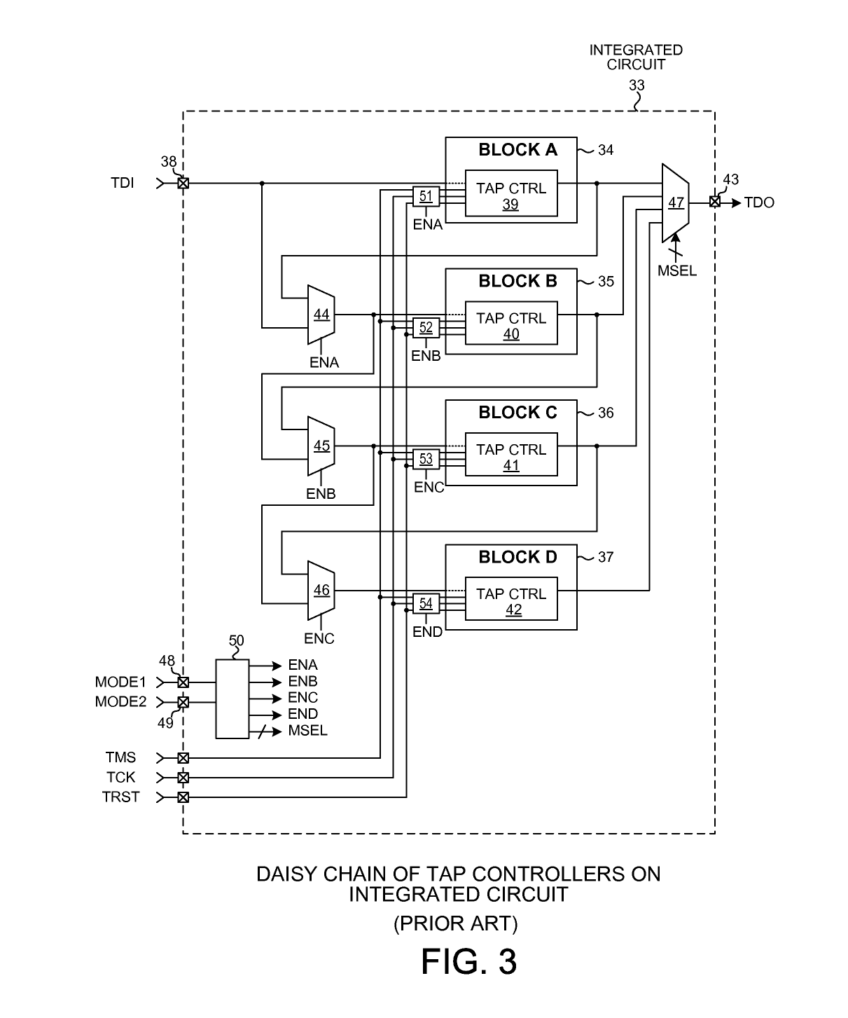

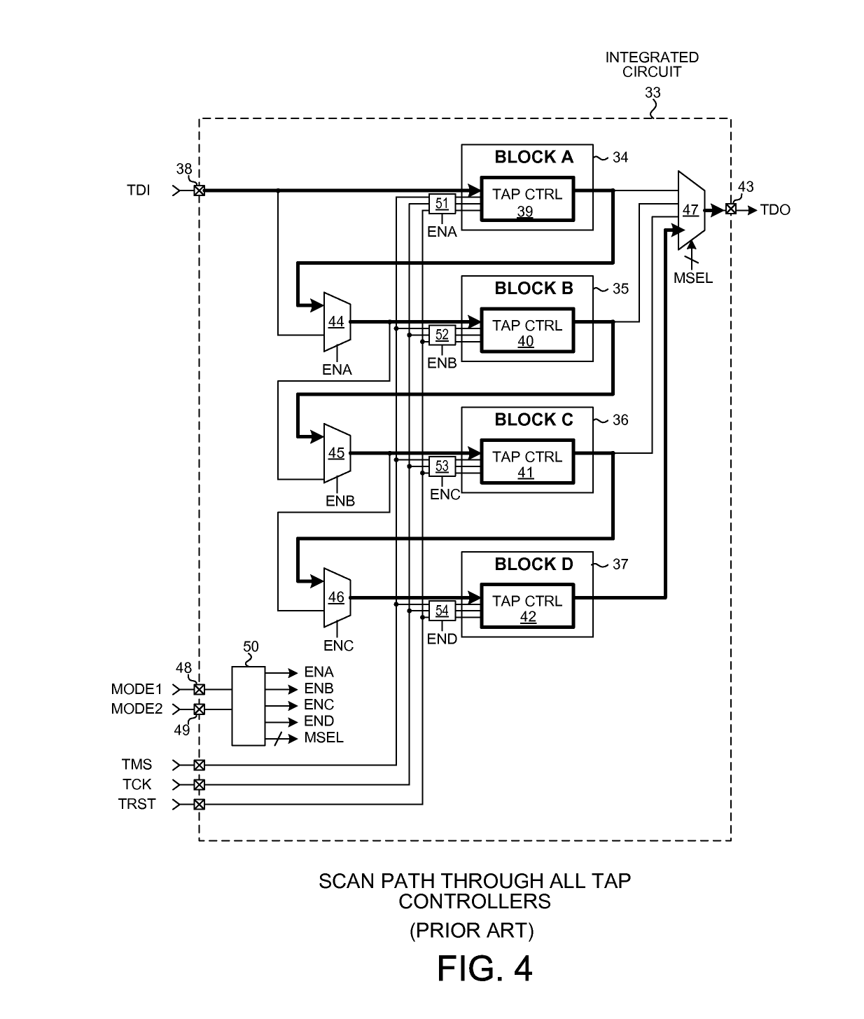

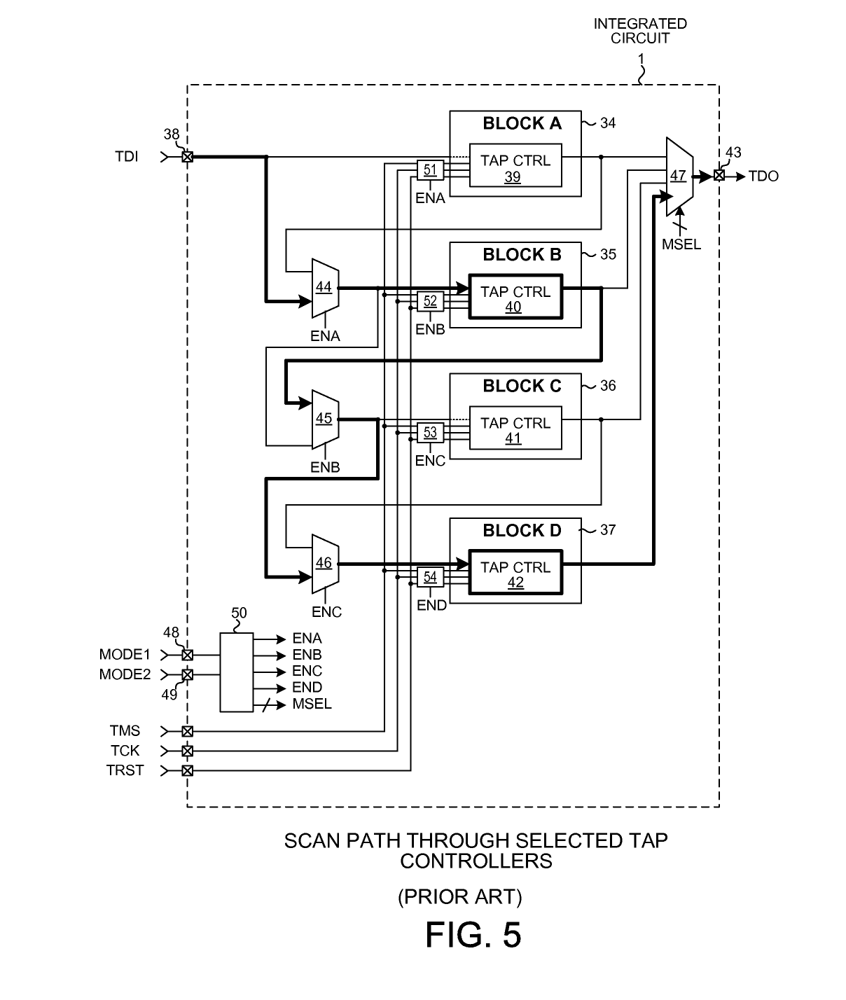

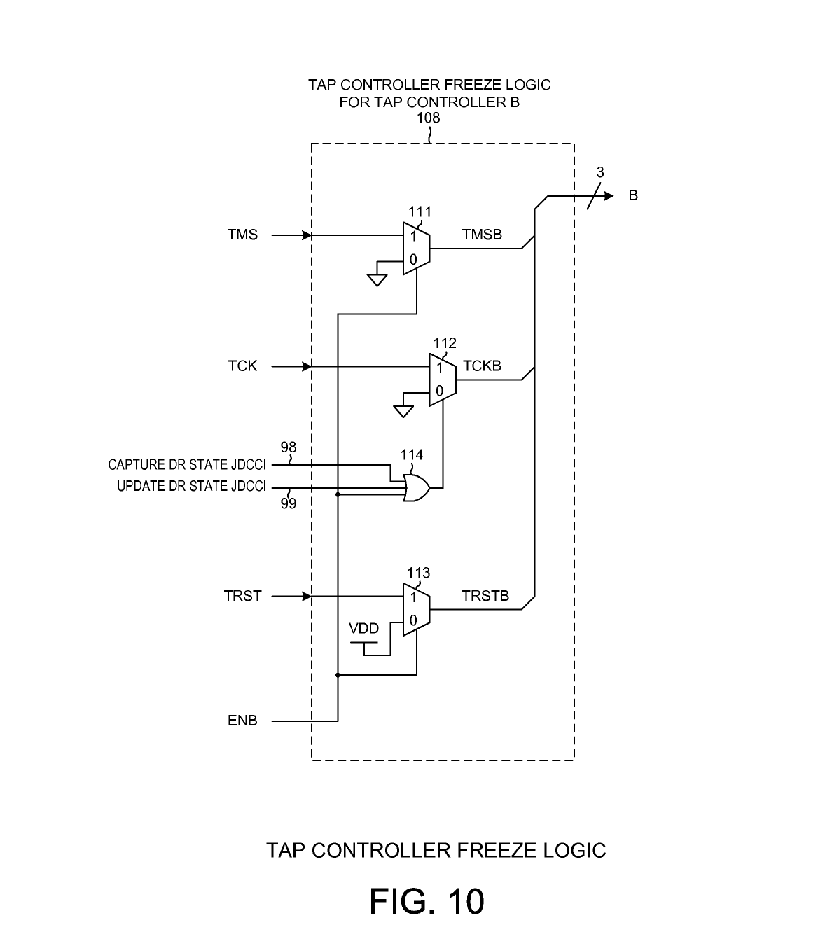

FIG. 10 is a more detailed circuit diagram of TAP controller freeze logic 108. The other two TAP controller freeze logic circuits 109 and 110 are of similar structure to the structure shown in FIG. 10. TAP controller freeze logic circuit 108 includes a circuit 111 for gating the signal TMS that is supplied onto the TMS port of TAP controller 72 as TMSB. TAP controller freeze logic circuit 108 also includes a circuit 112 for gating the signal TCK that is supplied onto the TCK port of TAP controller 72 as TCKB. TAP controller freeze logic circuit 108 includes a circuit 113 for gating the signal TRST that is supplied onto the TRST port of TAP controller 72 as TRSTB. Unlike the prior art circuit of FIGS. 2-5 where TAP controllers that are not incorporated into the daisy-chain scan path are reset, in the integrated circuit of FIGS. 6-10 the TAP controllers of the daisy-chain that are that are not included in the scan path are not reset but rather are rather are just disabled. Such a TAP controller is said to be frozen or is said to be in a freeze state. The TAP controllers that are not coupled to be part of the daisy-chain scan path therefore maintain their data register contents. TAP controller freeze logic circuit 108 freezes its associated TAP controller by holding the TMS signal passing into the TAP controller at a digital logic level low. If the TMS signal as supplied to a TAP controller is a digital low, then the FSM within the TAP controller cannot change state. In addition to preventing the TMS signal supplied to the TAP controller from being asserted to a digital logic high, the TAP controller is prevented from being clocked. Circuit 112 gates the TCK being supplied to the TAP controller and holds the TCK signal being supplied to the TAP controller at a digital logic low. Preventing the disabled TAP controller from being clocked reduces power consumption and also prevents the FSM of the TAP controller from changing state. In addition to preventing the TAP controller from receiving a high TMS signal and in addition to preventing the TAP controller from being clocked, the disabled TAP controller is also prevented from being reset. In the example of FIG. 10, when ENB is a digital logic low then multiplexing circuit 113 blocks the TRST signal from passing to the TRST port of TAP controller B but rather couples the TRST port of the TAP controller to a digital logic high. TRST is active low. Signal TRSTB as supplied to TAP controller B is held at the inactive digital logic high value when TAP controller B is disabled (when ENB is low).

Freezing auxiliary TAP controllers that are configured out of the daisy-chain scan path has an advantage as compared to forcing such TAP controllers to be reset. Consider an example in which all the TAP controllers 71-74 are required to perform a test. One of the TAP controllers B can only be clocked at 1 MHz, whereas the other TAP controllers A, C and D can be clocked at a faster 15 MHz. Using the self-reconfigurable daisy-chain circuit mechanism described above, the daisy-chain is configured so that the daisy-chain scan path only includes main TAP controller A and the slow TAP controller B. An instruction and data is shifted into this slow TAP controller B at the slow rate so that the TAP controller B supplies necessary test signals to circuitry to be tested. Once this TAP controller B has been set up to output the necessary test signals, the self-reconfigurable daisy-chain is reconfigured so that the daisy-chain scan path includes the other TAP controllers A, C and D and does not include the slow TAP controller B. The faster TAP controllers A, C and D can then be loaded with instructions and data using the faster clock without disturbing the slower TAP controller B that was previously set up. Test data captured by the faster TAP controllers can be serially shifted out of the scan path without disturbing the slower TAP controller B. In this example, all TAP controllers are used in the test. Where a lot of exercising of the faster TAP controllers A, C and D is involved in the test to be performed, the overall amount of time required to set up the test, to perform the test, and to read test results out of the circuit may be much reduced as compared to a conventional situation of having to clock all TAP controllers by the clock rate of the slowest TAP controller.

The explanation above of the freezing a selected TAP controller is, however, somewhat of a simplification. There are three conditions in which a disabled TAP controller is clocked so that it can change state.

The first condition is the condition after power up when the auxiliary TAP controllers are in the Test-Logic-Reset state when the main TAP controller has been loaded the JDCCI instruction to reconfigure the daisy-chain. After the loading of the instruction register of the main TAP controller with the JDCCI instruction, and after updating of the instruction register, then the data register of the main TAP controller corresponding to the JDCCI instruction is to be loaded with data. To do this, the main TAP controller transitions to the Select-DR state and then to the Capture-DR state. When the main TAP controller is in the Capture-DR state when the JDCCI instruction has been loaded, the CAPTURE DR STATE JDCCI digital signal as output by the main TAP controller is a digital high. The OR gates in the freeze logic blocks for the auxiliary TAP controllers allow TCK to pass to their respective auxiliary TAP controllers. TMS=0 for all the auxiliary TAP controllers. All the auxiliary TAP controllers therefore transition from the Test-Logic-Reset state to the Run-Test-Idle state so that they can later be enabled if desired.

The second condition is the condition in which there is a disabled TAP controller that is to be enabled. When the FSM of the main TAP controller is in the middle of Update-DR state when a JDCCI instruction has been loaded, all auxiliary TAP controllers (including the auxiliary TAP controller to be enabled) are supplied with a TCK as a result of UPDATE DR STATE JDCCI being a digital logic high for the next cycle. At the rising edge of this next TCK cycle, the disabled TAP controller (the TAP controller to be enabled) is being supplied with TMS=1, so the TAP controller to be enabled transitions from the Run-Test-Idle to Select-DR state along with the main TAP controller. All auxiliary TAP controllers in fact receive the TCK toggle at this time, but only a selected auxiliary TAP controller that is enabled or is to be enabled is supplied with TMS=1, so only such a selected TAP controller will transition state at this time. The other auxiliary TAP controllers whose enable bits (in the JDCCI register of the main TAP controller) are not set are not supplied with TMS=1 and do not transition state.

The third condition is the condition in which a previously enabled TAP controller is being disabled. When the FSM of the main TAP controller is in the Update-DR state when a JDCCI instruction has been loaded (to disable the auxiliary TAP controller), all auxiliary TAP controllers (including the auxiliary TAP controller to be disabled) are supplied with a TCK due to UPDATE DR STATE JDCCI being a digital logic high. At this time disabled TAP controller and an auxiliary TAP controller to be disabled will be supplied with TMS=0. Enabled TAP controllers are supplied with TMS=1. So when UPDATE DR STATE JDCCI is asserted to a digital logic high and all the auxiliary TAP controllers are clocked, only a TAP controller to be disabled (that has TMS=0) will transition from the Update-DR state to the Run-Test-Idle state.

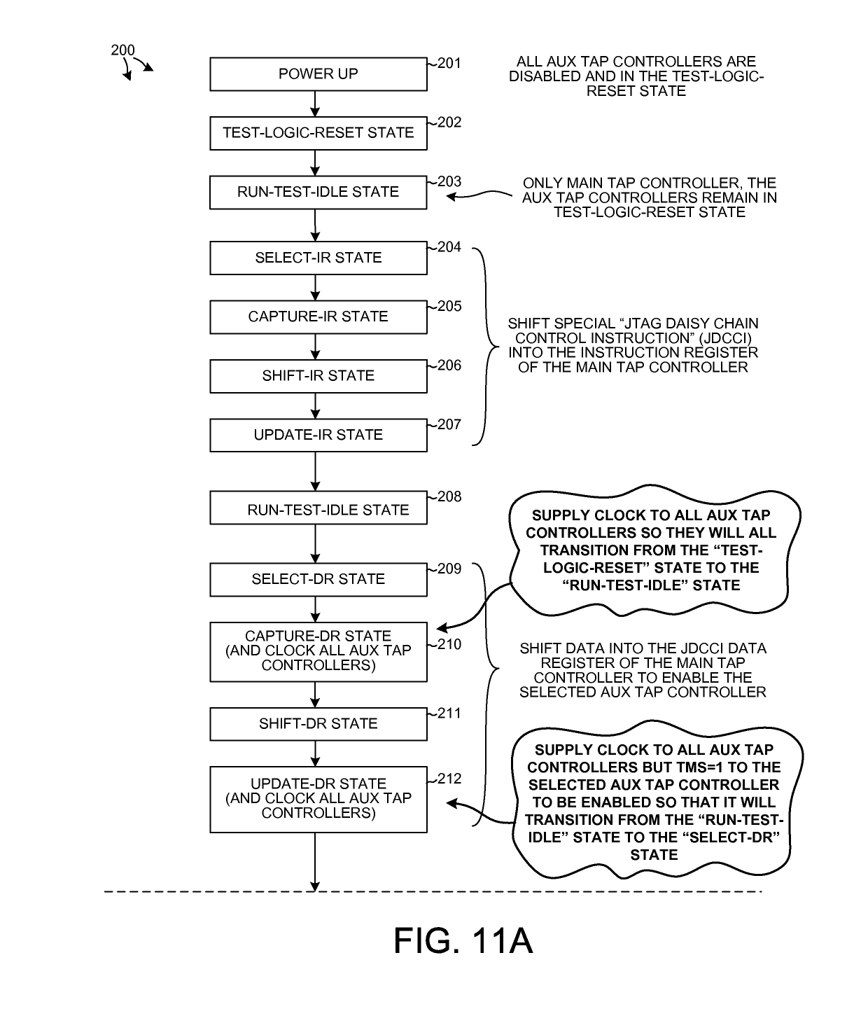

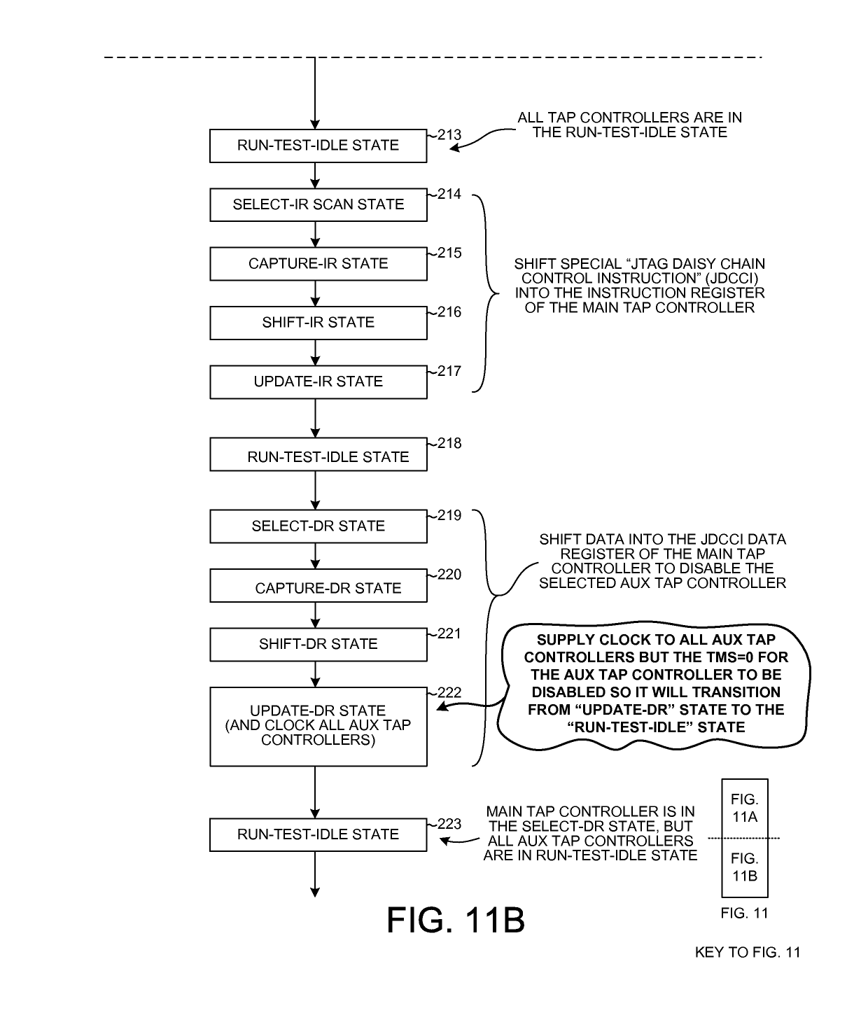

The flowchart of FIG. 11 illustrates a method 200 of enabling a disabled TAP controller B so that it will be included in the daisy-chain scan path, and then disabling that TAP controller B so it will be frozen and will not included in the daisy-chain scan path. The IEEE-1149.1 standard specifies that a TAP controller is to power up into the Test-Logic-Reset state. In the example of FIG. 11, all TAP controllers are initially unpowered and their instruction and data registers contain zero values. After powering up (step 201), all the TAP controllers A-D enter the Test-Logic-Reset state (step 202). Because all bit locations in the data registers of the main TAP controller A contain zeros, the multiplexing circuits 75-78 are controlled in this default condition so that the daisy-chain scan path involves only main TAP controller A 71. If information were to be shifted from TDI to TDO, it would only pass through main TAP controller A 71. In this Test-Logic-Reset state, if TMS is set to a digital one then the TAP controller A 71 will remain in the Test-Logic-Reset state. If TMS is set to a digital zero, and a TCK occurs, then the TAP controller 71 will move to the Run-Test-Idle state. Accordingly, the self-reconfigurable daisy-chain of TAP controllers powers up such that that the first daisy-chain TDI-to-TDO scan path through the daisy-chain passes through the main TAP controller A 71 and cannot pass through any other TAP controller.

Next (step 203), the signals on the TMS and TCK terminals are manipulated such that main TAP controller A 71 transitions to the run test idle state. All the other TAP controllers B-D remain in the Test-Logic-Reset state. The ENB, ENC and END signals are still digital zeros at this time, so instructions will not be loaded into the other TAP controllers B-D. The multiplexing circuits 112 in freeze logic 80 for the other TAP controllers 72-74 prevent these other auxiliary TAP controllers from being clocked. Only the main TAP controller A 71 therefore transitions to the Run-Test-Idle state. At this point, the main TAP controller A 71 is ready to load an instruction so the daisy-chain can be reconfigured. The instruction that causes the daisy-chain to be reconfigured is the special JDCCI instruction.

To load the special JDCCI instruction, the main TAP controller A is made to transition to the Select-IR state (step 204) by setting TMS to one for two cycles. Then TMS is set to zero for one cycle to move the main TAP controller A to the Capture-IR state (step 205). The change in the TMS signal on terminal 63 is blocked from reaching the disabled TAP controllers B-D by the freeze logic 80. The TMS signal on terminal 63 is then set to zero for one cycle, to move the main TAP controller A to the Shift-IR state (step 206). TMS is then set to zero in the Shift-IR state, and the main TAP controller A is clocked to shift an instruction into its instruction register. The bits that are shifted in are the bits of the JDCCI instruction. After the shifting in of the JDCCI instruction into the instruction register of the main TAP controller A, TMS is set to one for two cycles. This causes the main TAP controller A to transition to the Update-IR state (step 207). After an update of the instruction register, TMS is set to zero for one clock such that main TAP controller A returns to the Run-Test-Idle state (step 208).

Next the data register associated with the JDCCI instruction is to be loaded. The TMS signal on terminal 63 is set to one for one clock cycle. The change in the TMS signal on terminal 63 is still blocked from reaching the disabled auxiliary TAP controllers B-D by freeze logic 80. The change in TMS to a digital logic one causes the main TAP controller A to move to the Select-DR state (step 209). At this point, the FSM of the main TAP controller A selects for loading its data register associated with the currently loaded instruction. TMS is then set to a digital logic zero for two cycles to transition the main TAP controller A to the Capture-DR state (step 210).

All enabled TAP controllers in a JTAG daisy-chain must be in the same state and must move from state to state together in order for the outside JTAG test debugger to be able to control the daisy-chain scan path properly via the TAP interface. OR gate 114 (see FIG. 10) allows the auxiliary TAP controllers to be clocked during the Capture-DR state (when the main TAP controller is in the Capture-DR state at the end of execution of the JDCCI instruction) so that the auxiliary TAP controllers will transition from the Test-Logic-Reset state to the Run-Test-Idle state. All the auxiliary TAP controllers receive the TCK signal through their versions of OR gate 114. The transition of TCK to the auxiliary TAP controllers puts the TAP controller to enabled (TAP controller B in this example) into the same state as the main TAP controller A so that both TAP controllers A and B can then function together in the same daisy-chain scan path.

Next, TMS is set to zero to transition the main TAP controller A to the Shift-DR state (step 211). Data is then shifted into the data register for the JDCCI instruction. The bit location in the data register that corresponds to the auxiliary TAP controller B to be enabled is set to a digital logic one value. Once the data has been shifted into the last bit of the data register for the JDCCI instruction, then TMS is set to one for two cycles. This causes the FSM of the main TAP controller to transition to the Update-DR state (step 212) and to update the data register. The update causes ENA, ENB, ENC and END values that were shifted into corresponding bit locations in the data register to appear on conductors 81-83. The auxiliary TAP controller B is enabled at this time. No additional instruction is required to enable TAP controller B or to patch it into the daisy-chain scan path. In addition, in step 212, the UPDATE DR JDCCI signal output by the main TAP controller A is a digital high so all the auxiliary TAP controllers receive a TCK. The TAP controller B to be enabled is supplied with a TMS of one at this time, so TAP controller B transitions from the Run-Test-Idle state to the Select-DR state. In this example, TAP controllers C and D are not enabled and they do not receive a TMS=1 and then therefore remain in the Run-Test-Idle state. TMS is then set to zero for one cycle. This causes main TAP controller A to return to the Run-Test-Idle state (step 213).

At this point the daisy-chain of TAP controllers is configured so that a TDI-to-TDO daisy-chain scan path extends from TDI terminal 61, to the TDI port 90 of main TAP controller A, through main TAP controller A to the TDO port 91 of the main TAP controller A, to the upper input lead of multiplexing circuit 75, through the multiplexing circuit 75 to the TDI port 92 of auxiliary TAP controller B, through the auxiliary TAP controller B to TDO port 93, through output multiplexing circuit 78, and to TDO terminal 62. Auxiliary TAP controllers C and D remain disabled and are not in the scan path.

The remainder of FIG. 11 sets forth how the daisy-chain can be reconfigured to freeze TAP controller B and to disconnect TAP controller B so that the daisy-chain scan path no longer passes through the frozen TAP controller B. First, the JDCCI instruction is loaded into the instruction register of the main TAP controller A in steps 214-217. This operation is the same as described above in connection with steps 204-207 except that the scan path passes through the auxiliary TAP controller B in addition to the main TAP controller. It is, however, the loading of the JDCCI instruction into the instruction register of the main TAP controller A that is of interest here. After updating the instruction register in the main TAP controller A and passing through the Run-Test-Idle state (step 218), the data register (in the main TAP controller A) that is associated with the JDCCI instruction is to be loaded with data values such that the auxiliary TAP controller B can be disabled. The select, capture, shift and update steps 219-221 are similar to the select, capture, shift and update steps 209-221 described above except for the data value loaded and for an extra clocking of the just disabled TAP controller B in step 222. In step 222, all auxiliary TAP controllers receive the extra TCK when the main TAP controller A is the Update-DR state when the JDCCI instruction is loaded (due to CAPTURE DR STATE JDCCI being high), but auxiliary TAP controller B to be disabled has a TMS value of zero. If other auxiliary TAP controllers were enabled at this time, their TMS values would be one. In this example, the other TAP controllers C and D are disabled. Their TMS values are therefore zero. When the auxiliary TAP controllers are clocked (in step 222), the auxiliary TAP controller B transitions state from the Update-DR state to the Run-Test-Idle state. The other disabled TAP controllers C and D were previously in the Run-Test-Idle state and they remain in the Run-Test-Idle state. If the auxiliary TAP controller B being disabled were not clocked at this time, then the auxiliary TAP controller B that is being disabled would remain suspended in the Update-DR state.

Once the update of step 222 occurs, then TAP controller B is disabled. The daisy-chain of TAP controllers is configured so a TDI-to-TDO daisy-chain scan path extends from TDI terminal 61, to the TDI port 90 of main TAP controller A, through main TAP controller A to the TDO port 91 of the main TAP controller A, through output multiplexing circuit 78, and to TDO terminal 62. After step 222, the main TAP controller A is supplied with a TMS value of one. It therefore moves to the Select-DR state, whereas all the auxiliary TAP controllers B-D are disabled, have TMS values of zero, and are in the Run-Test-Idle state. Even though auxiliary TAP controller B is now disabled and is not any longer in the daisy-chain scan path, its data registers still store the values they stored just before auxiliary TAP controller B was disabled. The contents and outputs of the data registers of the disabled TAP controller B are not shifted, cleared, reset or disturbed in any way when TAP controller B is disabled and taken out of the daisy-chain scan path.

Accordingly, a selected one or more of the TAP controllers can be enabled and made part of the daisy-chain scan path by executing the JDCCI instruction and setting the bit in the data register corresponding to the selected TAP controller(s) to a digital logic one. Upon updating of the data register of the JDCCI instruction, the multiplexing circuits 75-78 are controlled so that the selected TAP controller(s) is/are included in the daisy-chain scan path. A selected one or more of the auxiliary TAP controllers can also be disabled so that it/they is/are cut out of the daisy-chain scan path. To disable a selected auxiliary TAP controller in this way, the JDCCI instruction is executed and the bit in the data register corresponding to the selected auxiliary TAP controller is set to a digital logic zero. Upon updating of the data register of the JDCCI instruction, the multiplexing circuits 75-68 are controlled so that the daisy-chain scan path bypasses the disabled TAP controller. The disabled TAP controller is not reset, but rather is frozen so that the content of its data registers remains unchanged.

Note that the dynamically self-reconfigurable daisy-chain of TAP controllers can be self-configured so that the main TAP controller becomes disabled and is not any longer a part of a TDI-to-TDO daisy-chain scan path. At this time the TDI-to-TDO daisy-chain scan path extends through other enabled auxiliary TAP controllers but does not extend through the main TAP controller. Once the dynamically self-reconfigurable daisy-chain of TAP controllers is in this configuration, the main TAP controller is no longer usable to reconfigure the daisy-chain until it is enabled again. There are two ways to re-enable the main TAP controller. First, the integrated circuit can be power cycled. At power on reset, all logic will be reset including the JDCCI data register in the main TAP controller. Second, TRST can be asserted high in an ATPG TEST mode. This will reset all the test logic in the integrated circuit including the JDCCI data register in the main TAP controller (i.e., TRST=1 with the MODE pin in ATPG TEST mode).

In one example, all the necessary logic to allow numerous TAP controllers to be reconfigurably interconnected to form a reconfigurable daisy-chain is provided in a single centrally-located Top Level Multiplexing Module (TLMM) block of circuitry. In the design of the overall integrated circuit, the TAP controllers of the various blocks are simply connected to the TLMM inputs and outputs as illustrated in FIG. 6. This modular TLMM architecture is easily expandable to accommodate adding additional TAP controllers. To add another TAP controller, another multiplexing circuit (such as multiplexing circuits 75-77) is added, the output multiplexing circuit 78 is made to have an additional data input lead, the data register for the JDCCI instruction is made to have another bit location to control the additional TAP controller, and another instance of the freeze logic (such as freeze logic circuits 108-110) is added. The same TLMM circuit block is usable in many different integrated circuit designs involving different combinations of types of other blocks and TAP controllers.

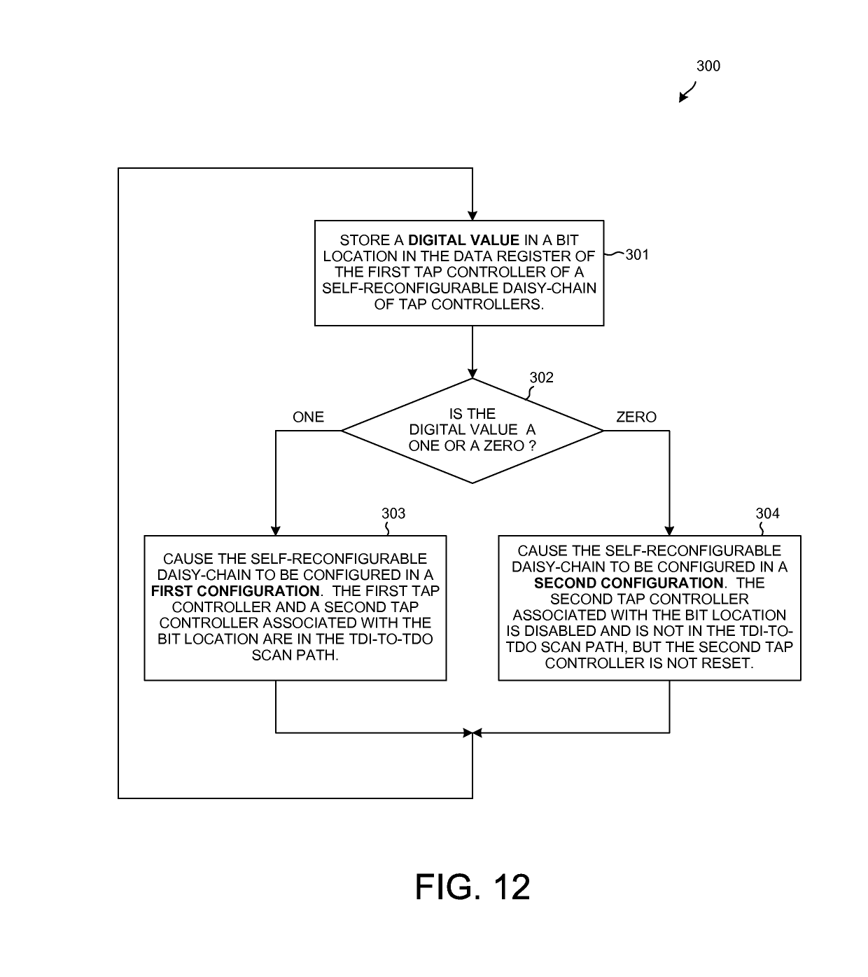

FIG. 12 is a flowchart of a method 300 involving a dynamically self-reconfigurable daisy-chain of TAP controllers. In a first step (step 301), a digital value is stored in a bit location in a first TAP controller of the daisy-chain. The bit location is associated with a second TAP controller of the self-reconfigurable daisy-chain. In one example, the digital value is stored by loading the special JDCCI instruction into the instruction register of the first TAP controller, executing the special JDCCI instruction, loading the bit location in the data register associated with the JDCCI instruction with the desired digital value, and then updating the data register. Next, if the digital value stored (step 302) in the bit location is a digital one, then the self-reconfigurable daisy chain is configured in a first configuration (step 330). In the first configuration both the first and second TAP controllers are in a TDI-to-TDO daisy-chain scan path. If, on the other hand, the digital value stored (step 302) in the bit location is a digital zero, then the self-reconfigurable daisy-chain is configured in a second configuration. In the second configuration the first TAP controller is in a TDI-to-TDO daisy-chain scan path, but the second TAP controller is not in the scan path. The second TAP controller is disabled but is not reset. The data register output signals as output by the data registers of the second TAP controller are not disturbed or changed when the reconfigurable daisy-chain is put into the second configuration.

Although certain specific embodiments are described above for instructional purposes, the teachings of this patent document have general applicability and are not limited to the specific embodiments described above. Accordingly, various modifications, adaptations, and combinations of the various features of the described specific embodiments can be practiced without departing from the scope of the claims that are set forth below.

What is claimed is:

1. An apparatus comprising:
a TDI (Test Data In) conductor;
a TDO (Test Data Out) conductor; and
a self-reconfigurable daisy-chain of TAP (Test Access Port) controllers comprising:
a first TAP controller; and
a second TAP controller, wherein the first TAP controller can configure the daisy-chain in a first configuration such that a first scan path extends from the TDI conductor, through the first TAP controller to a TDO port of the first TAP controller, to a TDI port of the second TAP controller, through the second TAP controller to a TDO port of the second TAP controller, and to the TDO conductor, and wherein the first TAP controller can configure the daisy-chain in a second configuration such that a second scan path extends from the TDI conductor, through the first TAP controller but not through the second TAP controller, and from the TDO port of the first TAP controller to the TDO conductor.

2. The apparatus of claim 1, wherein the daisy-chain can be configured to be in the first configuration such that the second TAP controller is a part of the first scan path and is then configured in the second configuration such that the second TAP controller is not a part of the second scan path, wherein the second TAP controller outputs data register output signals when the daisy-chain is in the first configuration, and wherein the second TAP controller continues to output the same data register output signals after the daisy-chain has been reconfigured to be in the second configuration.

3. The apparatus of claim 1, wherein the second TAP controller is not reset when the daisy-chain is configured in the second configuration.

4. The apparatus of claim 1, wherein the self-reconfigurable daisy-chain of TAP controllers further comprises:
a multiplexing circuit that is controllable by the first TAP controller to couple the TDI port of the second TAP controller to a selected one of: 1) the TDI conductor, and 2) the TDO port of the first TAP controller.

5. The apparatus of claim 1, wherein the self-reconfigurable daisy-chain of TAP controllers further comprises:
a multiplexing circuit that is controllable to couple the TDI port of the second TAP controller to a selected one of: 1) the TDI conductor, and 2) the TDO port of the first TAP controller, wherein the first TAP controller includes a data register, wherein if the data register stores a first digital value then the multiplexing circuit is controlled to couple the TDI port of the second TAP controller to the TDI conductor, whereas if the data register stores a second digital value then the multiplexing circuit is controlled to couple the TDI port of the second TAP controller to the TDO port of the first TAP controller.

6. The apparatus of claim 1, wherein the self-reconfigurable daisy-chain of TAP controllers further comprises:
a multiplexing circuit that is controllable by the first TAP controller to couple the TDO conductor to a selected one of: 1) the TDO port of the first TAP controller, and 2) the TDO port of the second TAP controller.

7. The apparatus of claim 1, wherein the first TAP controller comprises a data register, wherein the daisy-chain is configured into the first configuration if a first value is stored in the data register and the data register is updated, whereas the daisy-chain is configured into the second configuration if a second value is stored in the data register and the data register is updated.

8. The apparatus of claim 1, wherein the apparatus is an integrated circuit, wherein the TDI conductor is a first terminal of the integrated circuit, and wherein the TDO conductor is a second terminal of the integrated circuit.

9. The apparatus of claim 1, wherein the self-reconfigurable daisy-chain of TAP controllers further comprises:
a third TAP controller, wherein in the first configuration the scan path extends from the TDO port of the second TAP controller, then through the third TAP controller, and to the TDO conductor, and wherein in the second configuration the scan path does not extend through the third TAP controller.

10. The apparatus of claim 9, wherein the self-reconfigurable daisy-chain of TAP controllers powers up such that it is first configured into the second configuration.

11. An integrated circuit comprising:
a first TAP (Test Access Port) controller;
a second TAP controller having a TDI (Test Date In) port and a TDO (Test Data Out) port;
a third TAP controller having a TDI port and a TDO port;
a first multiplexing circuit that is controlled by the first TAP controller to couple one of the TDI port of the second TAP controller and the TDO port of the second TAP controller to the TDI port of the third TAP controller; and
a second multiplexing circuit that is controlled by the first TAP controller to couple one of the TDO port of the second TAP controller and the TDO port of the third TAP controller to a TDO conductor.

12. The integrated circuit of claim 11, wherein the first TAP controller comprises:
a data register having a bit location, wherein the first multiplexing circuit is controlled to couple the TDI port of the second TAP controller to the TDI port of the third TAP controller if a first digital value is stored in the bit location in the data register, whereas the first multiplexing circuit is controlled to couple the TDO port of the second TAP controller to the TDI port of the third TAP controller if a second digital value is stored in the bit location in the data register.

13. The integrated circuit of claim 12, wherein the first TAP controller further comprises:
an instruction register, wherein the data register can be loaded with data by shifting an instruction into the instruction register and then causing the first TAP controller to execute the instruction, wherein execution of the instruction by the first TAP controller allows the data to be shifted into the data register.

14. A method comprising:
storing a digital value in a data register of a first TAP (Test Access Port) controller, wherein the first TAP controller and a second TAP controller are parts of a reconfigurable daisy-chain of TAP controllers;
causing the reconfigurable daisy-chain of TAP controllers to be configured in a first configuration if the data value is a first digital logic value, wherein in the first configuration a first scan path extends from a TDI (Test Data In) conductor, through the first TAP controller to a TDO (Test Data Out) port of the first TAP controller, to a TDI port of a second TAP controller, through the second TAP controller to a TDO port of the second TAP controller, and to a TDO conductor; and
causing the reconfigurable daisy-chain of TAP controllers to be configured in a second configuration if the data register stores a second digital logic value, wherein in the second configuration a second scan path extends from the TDI conductor, through the first TAP controller to a TDO port of the first TAP controller, and to the TDO conductor without passing through the second TAP controller.

15. The method of claim 14, wherein said causing of the reconfigurable daisy-chain of TAP controllers to be configured in the second configuration occurs without resetting the second TAP controller.

16. The method of claim 14, wherein the second TAP controller has a data register, wherein the data register outputs signals at a time when the second TAP controller is enabled, and wherein said causing of the reconfigurable daisy-chain of TAP controllers to be configured in the second configuration causes the second TAP controller to switch from being enabled to being disabled without disturbing the signals output by the data register of the second TAP controller.

17. The method of claim 14, further comprising:
configuring the daisy-chain of TAP controllers in the first configuration such that the first and second TAP controllers are in the first scan path from the TDI conductor to the TDO conductor, and then configuring the daisy-chain of TAP controllers in the second configuration without resetting the second TAP controller such that the first TAP controller but not the second TAP controller is in the second scan path from the TDI conductor to the TDO conductor.

18. The method of claim 14, wherein the reconfigurable daisy-chain of TAP controllers powers up such that it is first configured into a configuration in which one and only one TAP controller is disposed in a scan path extending from the TDI conductor to the TDO conductor.

19. A method comprising:
configuring a daisy-chain of TAP (Test Access) controllers by storing one of a first digital value and a second digital value in a portion of a data register of one of the TAP controllers of the daisy-chain, wherein the data register includes a plurality of bit locations, wherein if the first digital value is stored in the portion of the data register then a TAP controller associated with the portion is included in a daisy-chain scan path from a TDI (Test Data In) conductor, through the daisy-chain scan path, and to a TDO (Test Data Out) conductor, whereas if the second digital value is stored in the portion of the data register then the TAP controller associated with the portion is not included in the daisy-chain scan path.

20. The method of claim 19, wherein the TDI conductor is a terminal of an integrated circuit, and wherein the TDO conductor is a terminal of the integrated circuit, wherein the portion is taken from the group consisting of: a single bit location and a plurality of bit locations, wherein the first digital value is taken from the group consisting of: a single bit value and a multi-bit value, and wherein the second digital value is taken from the group consisting of: a single bit value and a multi-bit value.

21. The method of claim 19, wherein the daisy-chain of TAP controllers is configured by loading one of the first and second digital values into the portion of the data register and then performing an update on the data register.

22. A method of manufacturing an integrated circuit comprising:
(a) fabricating a first TAP (Test Access Port) controller;
(b) fabricating a second TAP controller having a TDI (Test Data In) port and a TDO (Test Data Out) port;
(c) fabricating a third TAP controller having a TDI port and a TDO port;
(d) fabricating a first multiplexing circuit that is controllable by the first TAP controller to couple one of the TDI port of the second TAP controller and the TDO port of the second TAP controller to the TDI port of the third TAP controller; and
(e) fabricating a second multiplexing circuit that is controllable by the first TAP controller to couple one of the TDO port of the second TAP controller and the TDO port of the third TAP controller to a TDO conductor, wherein (a) through (e) occur substantially simultaneously when the integrated circuit is manufactured using an integrated circuit fabrication process.

23. The method of manufacturing the integrated circuit of claim 22, further comprising:
(f) fabricating freeze logic that can freeze the second TAP controller such that the second TAP controller is not reset and such that a data register of the second TAP is not disturbed when the second TAP controller is frozen, wherein the freeze logic freezes the second TAP controller if a bit location of a data register of the first TAP controller stores a first digital logic value, whereas the freeze logic does not freeze the second TAP controller if the bit location of the data register of the first TAP controller stores a second digital logic value.

24. An apparatus comprising:
a plurality of TAP controllers; and
means for configuring the plurality of TAP controllers such that if a first digital value is stored in a portion of a data register of a first of the TAP controllers then a second of the TAP controllers associated with the portion is included in a daisy-chain scan path from a TDI conductor, through the daisy-chain scan path, and to a TDO conductor, whereas if a second digital value is stored in the portion of the data register of the first TAP controller then the second TAP controller is not included in the daisy-chain scan path.

25. The apparatus of claim 24, wherein the means is for configuring the plurality of TAP controllers such that the second TAP controller can be made to output data register output signals when the second TAP controller is a part of the daisy-chain scan path and such that the second TAP controller can then be disabled such that it is not in the daisy-chain scan path and such that the second TAP controller continues to output the data register output signals after the second TAP controller has been disabled.

26. The apparatus of claim 24, wherein the means is for configuring the plurality of TAP controllers such that after the second TAP controller has been disabled the second TAP controller can then be enabled and included in a daisy-chain scan path extending from the TDI conductor, through the first TAP controller, through the second TAP controller, and to the TDO conductor.
